(19) United States
(12) Patent Application Publication
(10) Pub. No.: US 2005/0286231 A1
(43) Pub. Date: Dec. 29, 2005

(54) Heat sink with step fin

(76) Inventor: Kazuma Kishi, Ebina (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/157,854

(22) Filed: Jun. 22, 2005

(30) Foreign Application Priority Data
Jun. 24, 2004 (JP) 2004-185906

(51) Int. Cl. H05K 7/20

(52) U.S. Cl. 361/709; 165/80.3

(57) ABSTRACT

A heat sink with a fan is provided to be able to prevent clogging by dust at an admission port of a cooling air for radiating fins of the heat sink with a fan to maintain cooling effect expected of the heat sink with a fan over a long period of time. The heat sink with a fan comprises a heat-sink body, a plurality of radiating fins mounted on the heat-sink body, and a fan device that takes in a cooling air through gaps between the plurality of radiating fins. The plurality of radiating fins are provided with step differences that are disposed between adjacent radiating fins and at an admission side of a cooling air produced by the fan device and set on the basis of a length of dust.

### INCORPORATION BY REFERENCE

The present application claims priority from Japanese application 2004-185906 filed on Jun. 24, 2004, the content of which is hereby incorporated by reference into this application.

### BACKGROUND OF THE INVENTION

The present invention relates to a heat sink with a fan, having a plurality of radiating fins, and more particular, to a technique effectively applied to prevention of clogging by dust at an admission port of a cooling air for radiating fins of a heat sink with a fan.

In order to cool a high heat generating body such as CPU, etc., a heat sink with a fan, having a plurality of radiating fins is used. Conventionally, in order to increase a cooled area to improve a cooling capacity, radiating fins are made very narrow in pitch in view of cooling efficiency.

Therefore, there is caused a problem that clogging by dust is liable to be generated at an admission port of a cooling air for radiating fins of a heat sink with a fan whereby it is not possible to maintain an expected cooling effect over a long period of time.

Hereupon, there is conventionally proposed a heat sink with a fan, in which radiating fins in a region of high wind velocity are arranged at large intervals and radiating fins in a region of low wind velocity are arranged at small intervals (see, for example, JP-A-8-162787).

### SUMMARY OF THE INVENTION

In recent years, an increase in amount of heat generated by CPU, etc. makes it necessary to enhance a cooling efficiency of a heat sink with a fan. However, there is caused a problem that when radiating fins in a location, in which clogging by dust is liable to occur, are made large in intervals as described in JP-A-8-162787, a cooling efficiency is decreased.

It is an object of the invention to provide a heat sink with a fan, in which it is possible to prevent occurrence of clogging by dust at an admission port of a cooling air for radiating fins of the heat sink with a fan and to maintain an cooling effect expected of the heat sink with a fan over a long period of time.

An outline of a representative one of inventions disclosed in the present application will be simply described as follows.

A heat sink according to the invention comprises a heat-sink body, a plurality of radiating fins mounted on the heat-sink body, and a fan that takes in a cooling air into gaps between the plurality of radiating fins, and the plurality of radiating fins are provided with step differences, which are provided between adjacent radiating fins and at an admission port of a cooling air produced by the fan to be set on the basis of a length of dust.

An effect produced by a representative one of inventions disclosed in the present application will be briefly described below.

According to the invention, it is possible to prevent clogging by dust at an admission port of a cooling air for radiating fins of a heat sink with a fan to maintain an cooling effect expected of the heat sink with a fan over a long period of time.

Other objects, features and advantages of the invention will become apparent from the following description of the embodiments of the invention taken in conjunction with the accompanying drawings.

### BRIEF DESCRIPTION OF THE DRAWINGS

FIGS. 1A to 1C are views showing the construction of a heat sink with a fan, according to an embodiment of the invention, in which FIG. 1A is a side view showing the heat sink with a fan, FIG. 1B is a cross sectional view taken along the line IB-IB in FIG. 1A, and FIG. 1C is an enlarges view showing a part IC in FIG. 1B;

FIG. 2 is a perspective view showing an outward appearance of the heat sink with a fan, according to the embodiment of the invention;

FIGS. 3A to 3C are views showing the construction of a conventional heat sink with a fan in which FIG. 3A is a side view showing the conventional heat sink with a fan, FIG. 3B is a cross sectional view taken along the line IIIB-IIIB in FIG. 3A, and FIG. 3C is an enlarged view showing a part IIIB in FIG. 3B;

FIGS. 4A and 4B are views illustrating a method of manufacturing a heat sink part of a heat sink with a fan, according to an embodiment of the invention in which FIG. 4A is a view showing a heat sink after a plurality of C-shaped radiating fins are mounted on a heat-sink body, and FIG. 4B is a view showing the single C-shaped radiating fin;

FIGS. 5A and 5B are views showing the construction of a heat sink with a fan, according to another embodiment of the invention in which FIG. 5A is a side view showing the heat sink with a fan, and FIG. 5B is a cross sectional view taken along the line VB-VB in FIG. 5A; and

FIG. 6 is a view illustrating an example of intake of a cooling air in a heat sink with a fan, according to a further embodiment of the invention.

### DESCRIPTION OF THE PREFERRED EMBODIMENTS

Embodiments of the invention will be described hereinafter in detail with reference to the drawings. In addition, the same members are generally denoted by the same reference numerals in all the drawings illustrative of the embodiments, and a repeated explanation therefor is omitted.

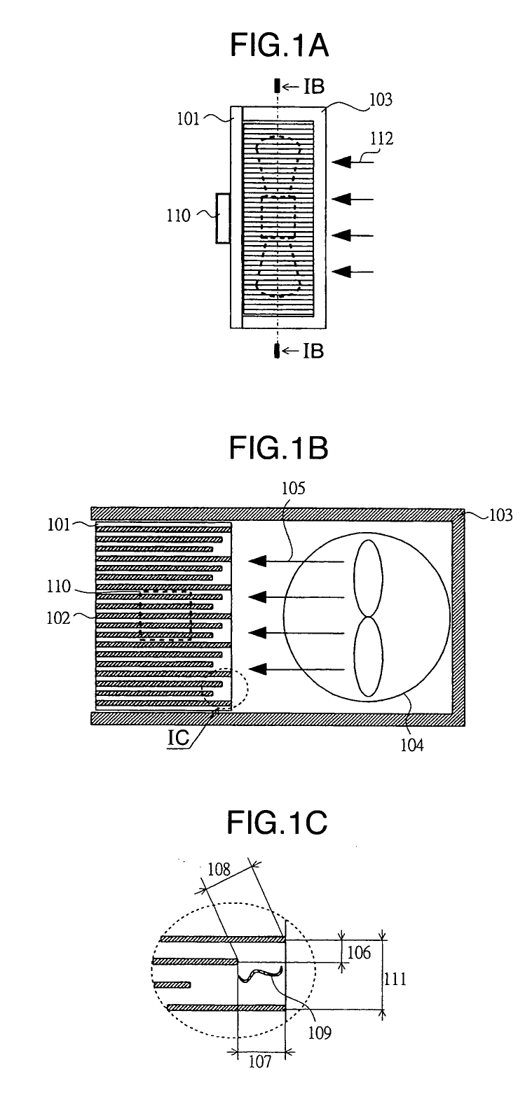

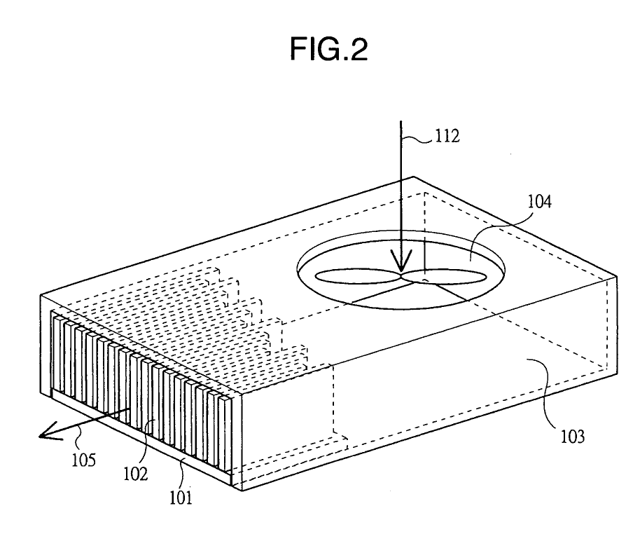

Referring to FIGS. 1A to 1C and 2, an example of the construction of a heat sink with a fan, according to an embodiment of the invention will be described.

In FIGS. 1A to 1C and 2, the heat sink with a fan comprises a heat-sink body 101 made of a material, such as aluminum, etc., having a good thermal conductivity, a plurality of radiating fins 102 provided on the heat-sink body 101 so as to protrude from the body, a cover member 103, and a fan device (fan) 104.

The plurality of radiating fins 102 include a step difference 107 between adjacent radiating fins 102 and at an admission port of a cooling air produced by the fan device 104.

The radiating fins 102 extending toward the admission port of a cooling air produced by the fan device 104 are different in extension length to form the step difference 107 between adjacent radiating fins 102. Step differences of the radiating fins 102 are provided in two stages, and a configuration of the step differences in two stages is repeatedly provided at an interval 111, at which the step differences are provided.

As shown in FIG. 2, the cover member 103 is provided to cover the heat-sink body 101 and the radiating fins 102, and the cover member 103 also covers a bottom surface of the heat sink with a fan, except the heat-sink body 101.

The fan device 104 is mounted in a state of being embedded in the cover member 103 of the heat sink with a fan, takes in an outside air 112 from above, and introduces a cooling air 105 toward the radiating fins 102 as shown in arrows in FIG. 1B to discharge the same through gaps between the radiating fins 102. The cooling air 105 passes between the radiating fins 102 to thereby cool a heat generating body 110 arranged under the heat-sink body 101.

In order to ensure a necessary cooling capacity, a fin pitch 106 of the radiating fins 102 is appropriately determined in view of surface area and pressure loss of the radiating fins 102, etc., and on the basis of the results of experiments, in which the fin pitch 106 is changed, the fin pitch 106 in the embodiment is determined to be in the order of 1 mm.

In addition, while step differences of the radiating fins 102 in the embodiment are provided in two stages as shown in FIG. 1B, the invention is not limited in number of stages of the step differences. Also, the invention is not limited to the fin pitch 106, the step differences 107, the interval 111, at which the step differences are provided, and a pattern of the arrangement.

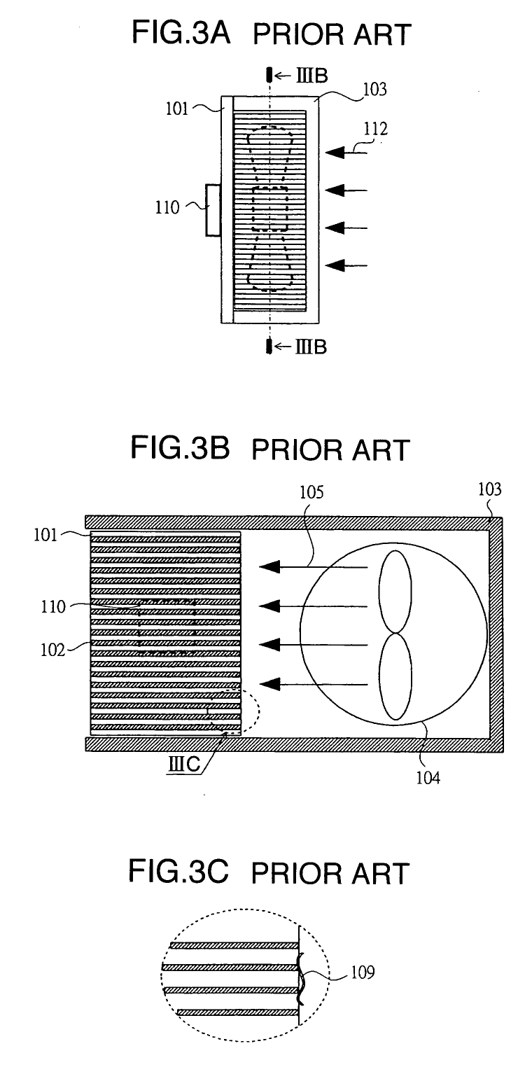

Referring to FIGS. 1A to 1C and 3A to 3C, a state of dust in the heat sink with a fan, according to the embodiment of the invention will be described.

In the conventional heat sink with a fan, radiating fins 102 are mounted as shown in FIG. 3B without the provision of the step difference 107 shown in FIG. 1C. In this arrangement, when a heat generating body 110 such as CPU, etc. generates a small amount of heat, the cooling capacity can be ensured although a fin pitch 106 is large, and so clogging by dust 109 is not occurred. Since an increase in amount of heat generated from a heat generating body 110 such as CPU, etc. in these days leads to narrowing of a fin pitch 106, dust 109 becomes liable to bridge between radiating fins 102 at an admission port of a cooling air as shown in FIG. 3C.

Further, since any step difference 107 is not provided, a further dust 109 adheres in a state of being caught by the bridging dust 109 to accelerate clogging at a rapidly accelerating rate, and thus there are increased those cases where an expected cooling effect can be produced only over a short period of time.

Hereupon, according to the embodiment, in order to prevent clogging due to dust bridge, the step differences 107 and the interval 111, at which the step differences 107 are provided, are provided at the admission port of a cooling air for the radiating fins 102 in view of a magnitude of dust 109, as shown in FIGS. 1A to 1C.

In this manner, mounted at the admission port of a cooling air for the radiating fins 102 are the radiating fins 102, in which the step differences 107 and the interval 111, at which the step differences 107 are provided, are provided in view of a magnitude of dust 109, whereby it is possible to prevent clogging due to bridge of dust 109 to maintain an cooling effect expected of the heat sink with a fan over a long period of time without clogging due to bridge of dust 109 at a rapidly accelerating rate.

Further, since the fin pitch 106 of the radiating fins 102 themselves is not made large, it is possible to cool the heat generating body 110 without a decrease in cooling efficiency.

Additionally, in the embodiment, the step differences 107 and the interval 111, at which the step differences 107 are provided, are set to be 3 mm or more from a result of that test, in which cotton linters (cotton powder) having a length of at most 3 mm and a thickness of at most 1.5 micrometer were used as dust for testing, in view of an usual office environment and a continuous running was kept for one month, and from a view point to make an apparent fin pitch 108 and the interval 111, at which the step differences 107 are provided, larger than that length of dust 109, which is set in view of the usual office environment.

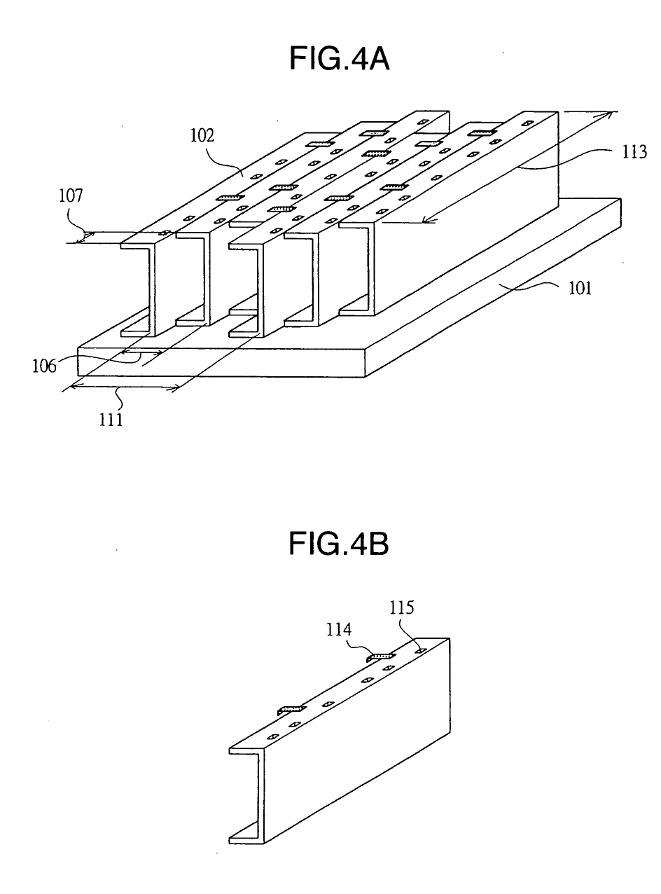

Referring to FIGS. 4A and 4B, an example of a method of manufacturing a heat sink part of the heat sink with a fan, according to the embodiment of the invention will be described.

The C-shaped radiating fin 102 is provided with hooks 114 and a plurality of holes 115, by which the hooks 114 are caught, such that the plurality of the C-shaped radiating fins 102 can be joined together with step differences therebetween. In addition, the holes 115 may extend through the radiating fin 102 or not as far as they can catch the hooks 114.

In the example shown in FIGS. 4A and 4B, the C-shaped radiating fin 102 is joined in plural whereby a plurality of radiating fins 102 are mounted on the heat-sink body 101.

Adjacent C-shaped radiating fins 102 are joined together by having the hooks 114 caught by the holes 115, by which the hooks are caught.

As shown in FIG. 4B, the holes 115, by which the hooks are caught, are provided in plural, and by shifting adjacent radiating fins 102 relative to each other and joining them, it becomes possible to use single radiating fins 102 having the same fin length 113 to manufacture a heat sink with step differences 107.

Thereby, manufacture is possible at a manufacturing cost equal to that of conventional heat sinks.

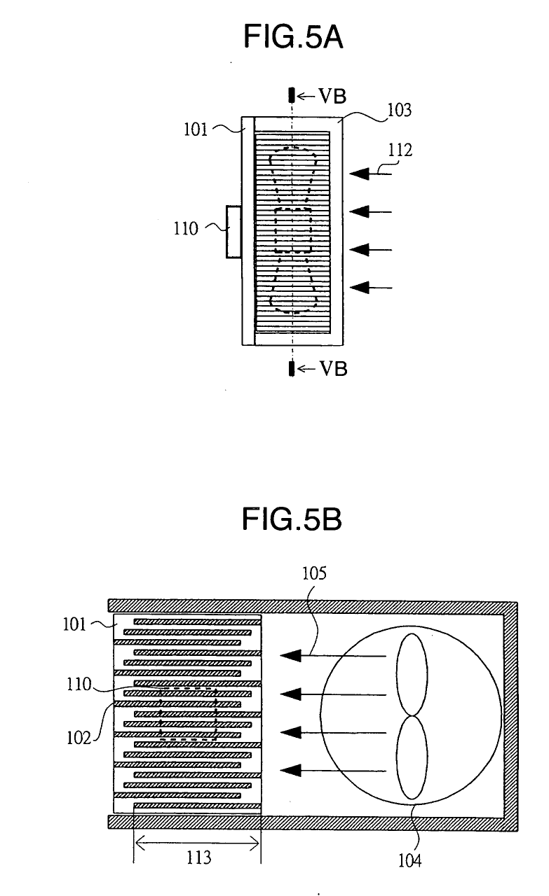

Referring to FIGS. 5A and 5B, the construction of a heat sink with a fan, according to another embodiment of the invention will be described.

In FIGS. 5A and 5B, radiating fins 102 of the heat sink with a fan are configured and mounted by means of the manufacturing method shown in FIGS. 4A and 4B, and the radiating fins 102 are the same in their fin length 113.

With such construction, clogging due to bridge of dust 109 can be prevented by step differences 107 of the radiating fins 102 even in the case where an outside air 112 is taken in from the radiating fins 102 in addition to flow of a cooling air 105 as shown in FIG. 1, and the cooling air 105 is caused to pass through gaps between the radiating fins 102 to be discharged upwardly of a fan device 104.

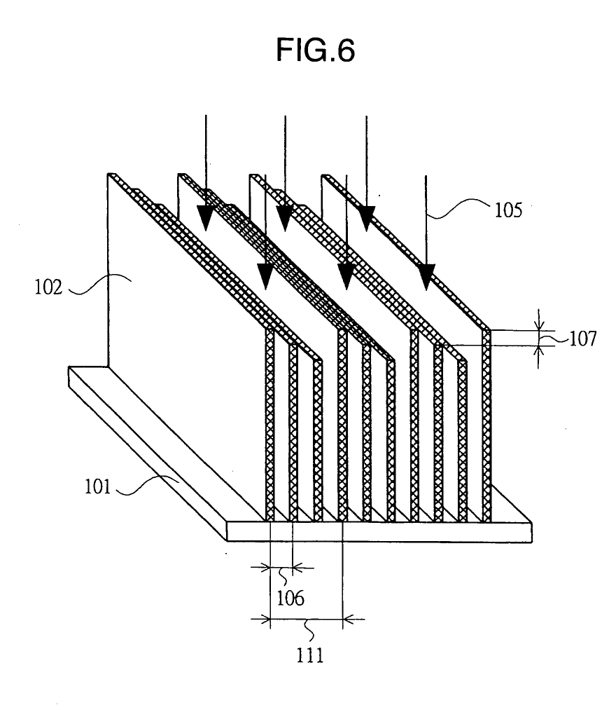

Referring to FIG. 6, an example of intake of a cooling air in a heat sink with a fan, according to a further embodiment of the invention will be described.

In the embodiments shown in FIGS. 1A to 1C and 5, the cooling air 105 is taken into the radiating fins 102 from laterally but, as shown in FIG. 6, step differences 107 can be provided on upper portions of radiating fins 102 on a heat-sink body 101 to take in a cooling air 105 from above the radiating fins 102.

Also in this case, at an admission port of a cooling air for the radiating fins 102 are provided the step differences 107 and intervals 111, at which the step differences 107 are provided, in view of a magnitude of dust 109. Therefore, clogging due to bridge of dust 109 can be prevented and thus it is possible to maintain an cooling effect expected of the heat sink with a fan over a long period of time.

Further, with the heat sink shaped as shown in FIG. 6, extrusion molding is possible and even with a configuration provided with step differences 107, manufacture is possible at a manufacturing cost equal to that of conventional heat sinks.

While the invention thought of by the inventors of the present application has been specifically described on the basis of the embodiments, the invention is not limited to the embodiments but it goes without saying that the invention is susceptible to various modifications within a range not departing from the gist thereof.

It should be further understood by those skilled in the art that although the foregoing description has been made on embodiments of the invention, the invention is not limited thereto and various changes and modifications may be made without departing from the spirit of the invention and the scope of the appended claims.

1. A heat sink comprising:
a base that receives heat generated by a heat generating part; and
a plurality of radiating fins arranged in parallel with each other on said base and provided at an inlet side of a cooling air with a step difference in a flow direction of the cooling air.

2. A heat sink according to claim 1, wherein an apparent pitch of tip ends of the radiating fins at the inlet side is 3 mm.

3. A heat sink according to claim 1, wherein the radiating fins are provided to have a step difference of at least 3 mm in the flow direction and a pitch of the radiating fins provided in parallel is at least 1 mm.

4. A heat sink according to claim 1, wherein the radiating fins are provided to have two or more step differences, which are made a unit to constitute a plurality of radiating fins.

5. A heat sink comprising:
a base that receives heat generated by a heat generating part; and
a plurality of C-shaped radiating fins provided on the base,
wherein the C-shaped radiating fins are provided in parallel with tip ends of the fins having a step difference in a flow direction of a cooling air.

6. A heat sink according to claim 5, wherein the C-shaped radiating fins comprise a fit portion corresponding to the step difference to be combined together.

7. A heat sink comprising:
a base that receives from one surface thereof heat generated by a heat generating part and provided at the other surface thereof with a plurality of radiating fins; and
a radiating fan arranged in parallel to the base to ventilate a cooling air through the radiating fins,
wherein the radiating fins are arranged in parallel on the base and provided at an inlet side of a cooling air with a step difference in a flow direction of the cooling air.
